(19) United States
(12) Patent Application Publication
(10) Pub. No.: US 2025/0210561 A1
(43) Pub. Date: Jun. 26, 2025

(54) BONDED STRUCTURE

(71) Applicant: TDK Corporation, Tokyo (JP)

(72) Inventors: Tomohisa MITOSE, Tokyo (JP); Kiryu IKEBE, Tokyo (JP); Takashi WATANABE, Tokyo (JP); Yuhei HOTTA, Tokyo (JP)

(73) Assignee: TDK Corporation, Tokyo (JP)

(21) Appl. No.: 18/846,340

(22) PCT Filed: Mar. 14, 2023
(86) PCT No.: PCT/JP2023/009859

§ 371 Date: Sep. 12, 2024

(30) Foreign Application Priority Data
Mar. 17, 2022 (JP) 2022-042685

(51) Int. Cl. H01L 23/00; H10H 20/857

(52) U.S. Cl. CPC H01L 24/16; H01L 24/13; H01L 2224/13082; H01L 2224/13083; H01L 2224/13084; H01L 2224/13111; H01L 2224/13144; H01L 2224/13155; H01L 2224/16227; H01L 2224/16503; H01L 2224/16507; H10H 20/857

(57) ABSTRACT

A bonded structure is a bonded structure in which an electronic component and a wiring substrate are bonded to each other, the bonded structure including, in order from the electronic component side: a first metal layer containing a metal forming an intermetallic compound with Sn; an intermetallic compound layer composed of an intermetallic compound containing Sn; and a second metal layer containing Sn, in which a thickness of the second metal layer is 50% or less of a total thickness of the first metal layer, the intermetallic compound layer, and the second metal layer.

### TECHNICAL FIELD

The present disclosure relates to a bonded structure.

### BACKGROUND ART

In recent years, digitalization has progressed, and along with this, the development of a technique for mounting electronic components on substrates is progressing. For example, until now, in assembling a fine electronic component, gold is employed for a terminal of the electronic component, Sn is applied to a facing wiring substrate side via plating or thin film deposition, and bonding is performed by solder bonding or diffusion bonding. When an electronic component and a wiring substrate are bonded to each other via Au plating and Sn plating, an intermetallic compound of Au and Sn tends to be formed at a bonding interface by eutectic reaction. One of problems of Sn—Au solder is brittleness of a Sn—Au-based intermetallic compound. As a method for overcoming the brittleness, a technique is disclosed in which an intermetallic compound is dispersed at a ratio of 5 to 50% as an area fraction of a bonded cross-section (for example, Patent Literature 1).

### CITATION LIST

### Patent Literature

Patent Literature 1: Japanese Unexamined Patent Publication No. 2003-286531

### SUMMARY OF INVENTION

### Technical Problem

However, since Sn has a low melting point, a metal element tends to be easily diffused in an alloy containing Sn. Therefore, in the structure in which the intermetallic compound is dispersed, there is a problem in that an element forming an intermetallic compound with Sn diffuses in an alloy containing Sn, and a Kirkendall void is generated at a location where the element forming an intermetallic compound with Sn existed.

An object of the present disclosure is to provide a bonded structure capable of suppressing Kirkendall void formation.

### Solution to Problem

A bonded structure according to the present disclosure is a bonded structure in which an electronic component and a wiring substrate are bonded to each other, the bonded structure including, in order from the electronic component side: a first metal layer containing a metal forming an intermetallic compound with Sn; an intermetallic compound layer composed of an intermetallic compound containing Sn; and a second metal layer containing Sn, in which a thickness of the second metal layer is 50% or less of a total thickness of the first metal layer, the intermetallic compound layer, and the second metal layer.

In the bonded structure according to the present disclosure, the thickness of the second metal layer is 50% or less of the total thickness of the first metal layer, the intermetallic compound layer, and the second metal layer. This means that a metal element forming an intermetallic compound with Sn in the initial state of bonding exists in a range wider than a central portion of the bonded structure. In this case, a concentration gradient serving as a driving force of diffusion of a metal element forming an intermetallic compound with Sn can be reduced, and Kirkendall void formation can be suppressed.

The first metal layer may contain Au. Au is a metal element in which a Kirkendall void is likely to be formed because Au is likely to form an intermetallic compound with Sn and Au is likely to diffuse in a layer containing Sn. On the other hand, by adopting the structure of the present disclosure, it is possible to suppress Kirkendall void formation even in the case of using Au.

The intermetallic compound layer may be present on the terminal of the wiring substrate. When the intermetallic compound layer containing Sn is present on the terminal of the wiring substrate, the concentration gradient of the metal element forming an intermetallic compound with Sn is low, diffusion hardly occurs, and Kirkendall void formation can be suppressed.

The terminal of the wiring substrate may have a conductive film containing Ni formed on a surface thereof. The conductive film containing Ni can suppress a reaction between the inside of the terminal of the wiring substrate and the metal element forming an intermetallic compound with Sn. This makes it possible to suppress the diffusion length extension of the metal element forming an intermetallic compound with Sn and to suppress Kirkendall void formation.

The volume ratio of the second metal layer may be 50% or less of a total volume of the first metal layer, the intermetallic compound layer, and the second metal layer. This makes it difficult for the metal element forming an intermetallic compound with Sn to diffuse, and Kirkendall void formation can be suppressed.

The volume ratio of the first metal layer may be 50% or less of a total volume of the first metal layer, the intermetallic compound layer, and the second metal layer. By reducing the volume of the first metal layer containing a metal element forming an intermetallic compound with Sn, the element to be diffused can be reduced, and Kirkendall void formation can be suppressed.

A bonded structure according to the present disclosure is a bonded structure in which an electronic component and a wiring substrate are bonded to each other, the bonded structure including, in order from the electronic component side: a first metal layer containing a metal forming an intermetallic compound with Sn; and an intermetallic compound layer composed of an intermetallic compound containing Sn, in which the intermetallic compound layer is present on a terminal of the wiring substrate.

The bonded structure according to the present disclosure is not a eutectic structure but a stacked structure of the first metal layer containing a metal forming an intermetallic compound with Sn and an intermetallic compound containing Sn. Furthermore, the intermetallic compound layer reaches the terminal of the wiring substrate. Therefore, the concentration gradient of the metal element forming an intermetallic compound with Sn, which serves a driving force of diffusion, can be reduced, and Kirkendall void formation can be suppressed.

The terminal of the wiring substrate may have a conductive film containing Ni formed on a surface thereof. The conductive film containing Ni can suppress a reaction between the inside of the terminal of the wiring substrate and the metal element forming an intermetallic compound with Sn. This makes it possible to suppress the diffusion length extension of the metal element forming an intermetallic compound with Sn and to suppress Kirkendall void formation.

A bonded structure according to the present disclosure is a bonded structure in which an electronic component and a wiring substrate are bonded to each other, the bonded structure including: a first metal layer containing a metal forming an intermetallic compound with Sn; an intermetallic compound layer composed of an intermetallic compound containing Sn; and a second metal layer containing Sn, in which a volume ratio of the second metal layer may be 50% or less of a total volume of the first metal layer, the intermetallic compound layer, and the second metal layer.

In the bonded structure according to the present disclosure, the volume ratio of the second metal layer is 50% or less of a total volume of the first metal layer, the intermetallic compound layer, and the second metal layer. This means that a metal element forming an intermetallic compound with Sn in the initial state of bonding exists in a range wider than a central portion of the bonded structure. In this case, a concentration gradient serving as a driving force of diffusion of a metal element forming an intermetallic compound with Sn can be reduced, and Kirkendall void formation can be suppressed.

### Advantageous Effects of Invention

According to the present disclosure, it is possible to provide a bonded structure capable of suppressing Kirkendall void formation.

### BRIEF DESCRIPTION OF DRAWINGS

FIG. 1 is a schematic cross-sectional view illustrating a mounting board including a bonded structure according to an embodiment of the present disclosure.

FIG. 2 is a schematic cross-sectional view illustrating a wiring substrate to which a bonded structure according to an embodiment of the present disclosure is applied.

FIG. 3 is a schematic cross-sectional view illustrating an example of a stacked structure of the bonded structure.

FIG. 4 is a schematic cross-sectional view illustrating an example of the stacked structure of the bonded structure.

FIG. 5 is a view illustrating an example of an SEM image.

FIG. 6 is a view for describing a method for bonding an electronic component and a wiring substrate.

FIG. 7 is a table indicating measurement results of an example and a comparative example.

FIG. 8 is a schematic cross-sectional view illustrating an example of the stacked structure of the bonded structure.

### DESCRIPTION OF EMBODIMENTS

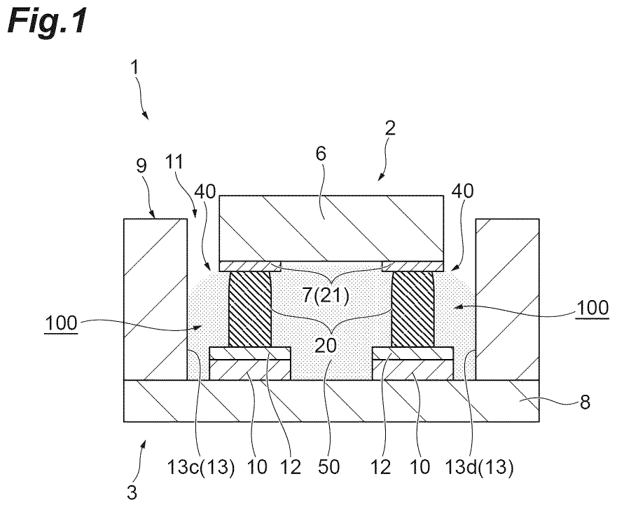

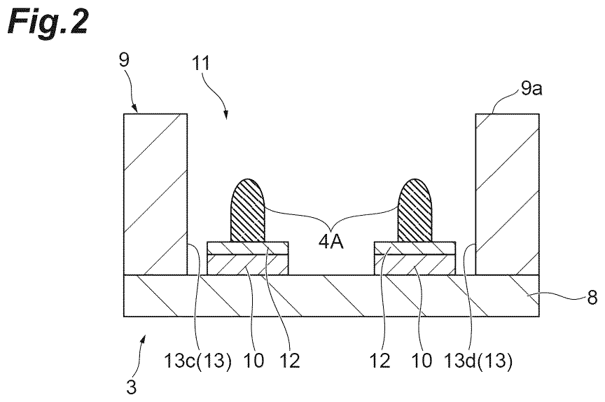

Referring to FIGS. 1 and 2, a bonded structure 100 according to an embodiment of the present disclosure will be described. FIG. 1 is a schematic cross-sectional view of a mounting board 1 including the bonded structure 100 according to an embodiment of the present disclosure. FIG. 2 is a schematic cross-sectional view illustrating a wiring substrate 3 to which a bonded structure 100 according to an embodiment of the present disclosure is applied.

As illustrated in FIG. 1, the mounting board 1 includes an electronic component 2 and the wiring substrate 3. The mounting board 1 is configured by mounting the electronic component 2 on the wiring substrate 3 via a bonding layer 40.

The electronic component 2 includes a body portion 6 and a pair of terminals 7. The body portion 6 is a member for exhibiting a function as the electronic component 2. The terminals 7 are metal portions formed on a main surface of the body portion 6. The electronic component 2 is configured of, for example, a micro LED, or the like. The micro LED is a component emitting light according to an input from the wiring substrate 3.

The wiring substrate 3 includes a base material 8, a wall 9, and a pair of terminals 10. The base material 8 is a flat plate-shaped body portion of the wiring substrate 3. The wall 9 is a member formed of an insulator formed on an upper surface of the base material 8. As a material for the wall 9, for example, a resin material such as an epoxy resin, an acrylic resin, a phenol resin, a melamine resin, a urea resin, or an alkyd resin is adopted. Particularly preferably, as a material for the wall 9, an epoxy resin or an acrylic resin is adopted. The terminals 10 are metal portions formed on a main surface of the base material 8. As a material for the terminals 10, Ni, Cu, Ti, Cr, Al, Mo, Pt, Au, an alloy selected from at least two of them, or the like is adopted. The terminal 10 has a conductive film 12 formed on a surface thereof. As a material for the conductive film 12, a film of Ti, Cu, Ni, Al, Mo, Cr, Ag, or the like, a film in which metal particles and a binder are mixed, or the like is adopted.

A Sn layer 20 is a layer containing Sn that bonds the terminals 7 of the electronic component 2 and the terminals 10 of the wiring substrate 3. Before assembly, the wiring substrate 3 includes a bonding material 4A in a state of being disposed on the upper surface of the conductive film 12 (see FIG. 2). The bonding material 4A functions as solder. During assembly, solder bonding is performed after the terminals 10, the conductive film 12, the bonding material 4A, and the terminals 7 are stacked.

A recess 11 is formed in the wall 9. The recess 11 is configured by a through hole passing through the wall 9. Thus, the upper surface of the base material 8 is exposed on the bottom side of the recess 11. The recess 11 has a rectangular shape as viewed in the thickness direction of the wiring substrate 3. The terminals 7, the terminals 10, the conductive film 12, and the Sn layer 20 are disposed in the recess 11 formed in the wall 9 so as to be surrounded by the wall 9. Slight gaps are formed between four inner side surfaces of the recess 11 (that is, inner side surfaces of the wall 9) and the terminals 7, the terminals 10, the conductive film 12, and the Sn layer 20.

A filling material 30 is disposed between the electronic component 2 and the Sn layer 20, and the wall 9 in the recess 11. Thus, the electronic component 2 can be made difficult to be separated from the wiring substrate 3 by being supported by the filling material 50. Furthermore, a force applied to the electronic component 2, the Sn layer 20, and the terminals 7 and 10 is relaxed, and reliability can be improved. As a material for the filling material 50, for example, an epoxy resin, an acrylic resin, a phenol resin, a melamine resin, a urea resin, an alkyd resin, a mixture thereof, or a mixture of the above-described resin materials with SiOx, ceramics, and the like is adopted. Particularly preferably, as a material for the filling material 50, an epoxy resin or an acrylic resin is adopted.

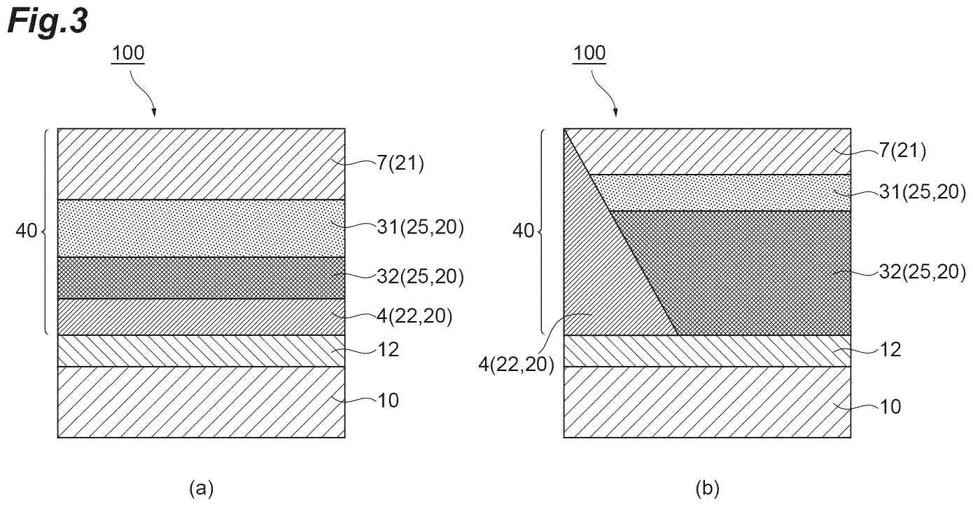

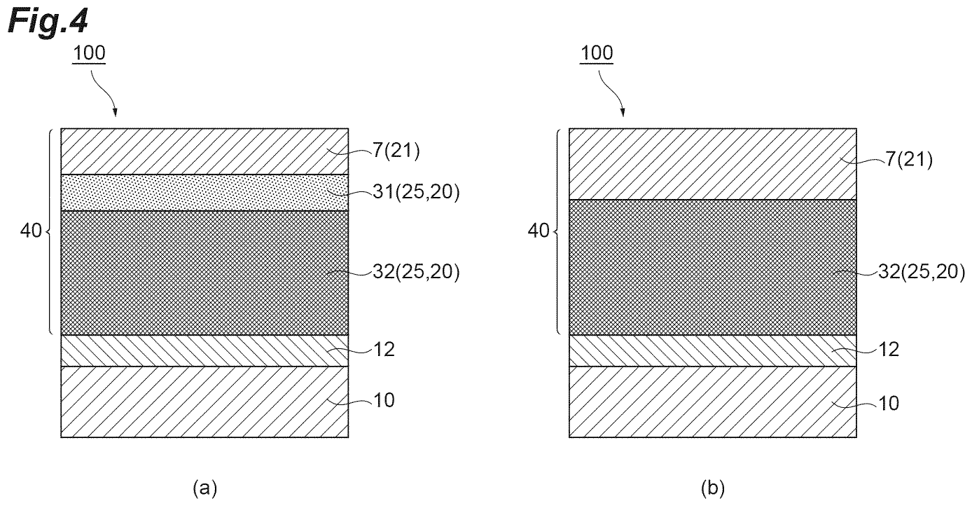

Next, referring to FIGS. 3 and 4, the bonded structure 100 according to the present embodiment will be described in more detail. In an example of FIG. 3(a), the bonded structure 100 includes a terminal 7, an intermetallic compound layer 25, a bonding material 4, a conductive film 12, and a terminal 10 in order from the electronic component 2 side. The bonded structure 100 includes, in order from the electronic component 2 side, a first metal layer 21 containing a first metal forming an intermetallic compound with Sn, an intermetallic compound layer 25 composed of an intermetallic compound containing Sn, and a second metal layer 22 composed of a second metal containing Sn. Here, the terminal 7 of the electronic component 2 corresponds to the first metal layer 21, and the bonding material 4 corresponds to the second metal layer 22. The intermetallic compound layer 25 is provided between the terminal 7 and the bonding material 4, and is composed of an intermetallic compound of a bonding material containing Sn and the first metal.

Note that, in the following description, a stacked structure including the terminal 7 containing Au and the Sn layer 20 may be referred to as the bonding layer 40.

The second metal of the bonding material 4 may contain Sn or may be made of an alloy containing Sn. The second metal may contain, in addition to Sn, an element lowering a melting point of Sn. Examples of the element lowering a melting point of Sn include Bi.

The first metal of the terminal 7 is any metal of Au, Cu, Ni, Ag, and Pd, or an alloy selected from at least two of these metals. The first metal may be a metal containing at least Au.

The intermetallic compound layer 25 is formed by diffusing the first metal of the terminal 7 toward the wiring substrate 3 side. The intermetallic compound layer 25 is composed of an intermetallic compound of the first metal of the terminal 7 and the second metal containing Sn of the bonding material 4. Here, the intermetallic compound layer 25 includes a first layer 31 and a second layer 32. For example, the first layer 31 is made of AuSn₂. The second layer 32 is made of AuSn₄. Note that, on the terminal 10 (on the conductive film 12), the bonding material 4 may be partially formed, and the intermetallic compound layer 25 may be partially present.

In an example of FIG. 3(b), the bonded structure 100 includes the terminal 7, the intermetallic compound layer 25, the conductive film 12, and the terminal 10 in order from the electronic component 2 side. Furthermore, the bonding material 4 is disposed on the lateral side of the terminal 7 and the intermetallic compound layer 25. The bonded structure 100 includes, in order from the electronic component 2 side, the first metal layer 21 containing a first metal forming an intermetallic compound with Sn, and the intermetallic compound layer 25 composed of an intermetallic compound containing Sn. The intermetallic compound layer 25 is present on the terminal 10 of the wiring substrate 3. Here, since the terminal 10 has the conductive film 12 on the upper surface, the intermetallic compound layer 25 is present on the conductive film 12. The intermetallic compound layer 25 includes the first layer 31 and the second layer 32. For example, the first layer 31 is made of AuSn₂. The second layer 32 is made of AuSn₄. The bonding material 4 has a triangular shape extending to the terminal 7, but the shape of the bonding material 4 is not particularly limited, and there is also no limitation in that the bonding material 4 extends to any layer.

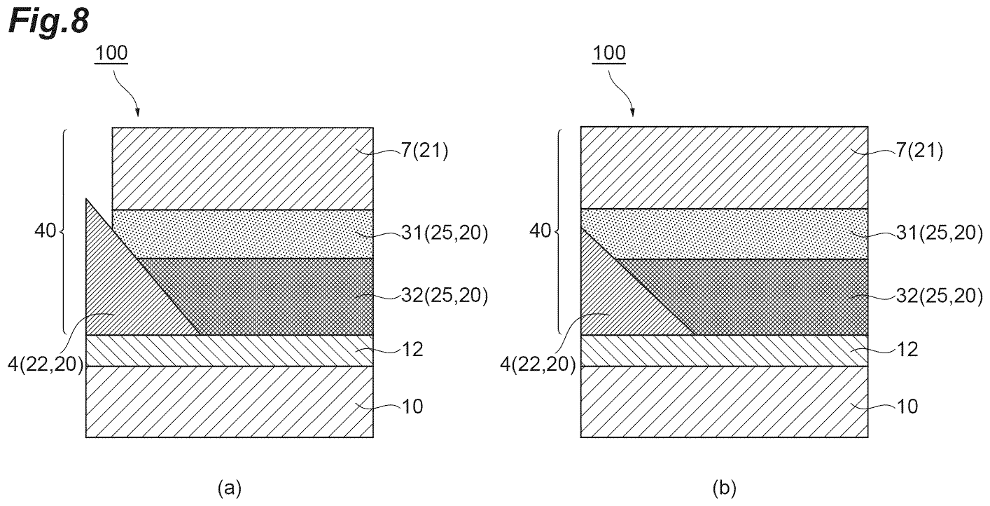

Note that, as illustrated in FIG. 8, the bonding material 4 may not be in contact with the terminal 7. In an example illustrated in FIG. 8(a), the triangular bonding material 4 extends so as to be laterally displaced with respect to the terminal 7, so that the bonding material 4 has a positional relationship of not contacting the terminal 7. In an example illustrated in FIG. 8(b), the triangular bonding material 4 does not extend to the terminal 7, so that the bonding material 4 has a positional relationship of not contacting the terminal 7.

In an example of FIG. 4(a), all the bonding material 4 in FIG. 3 are the intermetallic compound layer 25. The bonded structure 100 includes the terminal 7, the intermetallic compound layer 25, the conductive film 12, and the terminal 10 in order from the electronic component 2 side. The bonded structure 100 includes, in order from the electronic component 2 side, the first metal layer 21 containing a first metal forming an intermetallic compound with Sn, and the intermetallic compound layer 25 composed of an intermetallic compound containing

Sn. The intermetallic compound layer 25 is present on the terminal 10 of the wiring substrate 3. The intermetallic compound layer 25 includes the first layer 31 and the second layer 32. For example, the first layer 31 is made of AuSn₂. The second layer 32 is made of AuSn₄.

In an example of FIG. 4(b), the structure of the intermetallic compound layer 25 is different from that of FIG. 4(a). The bonded structure 100 includes the terminal 7, the intermetallic compound layer 25, the conductive film 12, and the terminal 10 in order from the electronic component 2 side. The bonded structure 100 includes, in order from the electronic component 2 side, the first metal layer 21 containing a first metal forming an intermetallic compound with Sn, and the intermetallic compound layer 25 composed of an intermetallic compound containing Sn. The intermetallic compound layer 25 is present on the terminal 10 of the wiring substrate 3. The intermetallic compound layer 25 includes a third layer 33. For example, the third layer 33 is formed with the AuSn-based intermetallic compound layer 25, and is made of, for example, AuSn₄.

Next, the thickness and area of each layer of the bonded structure 100 will be described. The ratio of the thickness of a specific layer described below indicates the ratio of the thickness of the specific layer to the thickness of the entire bonding layer 40. Furthermore, the ratio of the volume of a specific layer indicates the ratio of the thickness of the specific layer to the volume of the entire bonding layer 40.

In the bonded structure 100 illustrated in FIG. 3(a), the thickness of the bonding material 4 (second metal layer 22) is preferably 50% or less, more preferably 35% or less, and further preferably 10% or less of the total thickness of the terminal 7 (first metal layer 21), the intermetallic compound layer 25, and the bonding material 4. Note that, the lower limit value is not particularly limited, and the bonding material 4 may be eliminated as illustrated in FIG. 4. That is, the thickness of the bonding material 4 (second metal layer 22) may be 0% or more of the total thickness of the terminal 7 (first metal layer 21), the intermetallic compound layer 25, and the bonding material 4.

The volume ratio of the bonding material 4 (second metal layer 22) is preferably 50% or less and more preferably 14% or less of the total volume of the terminal 7 (first metal layer 21), the intermetallic compound layer 25, and the bonding material 4. Note that, the lower limit value is not particularly limited, and the bonding material 4 may be eliminated as illustrated in FIG. 4.

The volume ratio of the terminal 7 (first metal layer 21) is preferably 50% or less and more preferably 30% or less of the total volume of the terminal 7 (first metal layer 21), the intermetallic compound layer 25, and the bonding material 4 (second metal layer 22). The lower limit value is not particularly limited, but the volume ratio of the terminal 7 (first metal layer 21) is preferably 4% or more of the total volume of the terminal 7 (first metal layer 21), the intermetallic compound layer 25, and the bonding material 4 (second metal layer 22).

In the bonded structure 100 illustrated in FIG. 3(b), the volume ratio of the bonding material 4 (second metal layer 22) is preferably 50% or less and more preferably 12% or less of the total volume of the terminal 7 (first metal layer 21), the intermetallic compound layer 25, and the bonding material 4.

The volume ratio of the terminal 7 (first metal layer 21) is preferably 50% or less and more preferably 27% or less of the total volume of the terminal 7 (first metal layer 21), the intermetallic compound layer 25, and the bonding material 4 (second metal layer 22). The lower limit value is not particularly limited, but the volume ratio of the terminal 7 (first metal layer 21) is preferably 4% or more of the total volume of the terminal 7 (first metal layer 21), the intermetallic compound layer 25, and the bonding material 4 (second metal layer 22).

In the bonded structure 100 illustrated in FIGS. 4(a) and 4(b), the volume ratio of the terminal 7 (first metal layer 21) is preferably 50% or less and more preferably 30% or less of the total volume of the terminal 7 (first metal layer 21) and the intermetallic compound layer 25. The lower limit value is not particularly limited, but the volume ratio of the terminal 7 (first metal layer 21) is preferably 4% or more of the total volume of the terminal 7 (first metal layer 21) and the intermetallic compound layer 25.

Note that, the layer structure in FIGS. 3 and 4 is an example. For example, the number of layers in the intermetallic compound layer 25 is not particularly limited. For example, the intermetallic compound layer 25 may further include an AuSn layer.

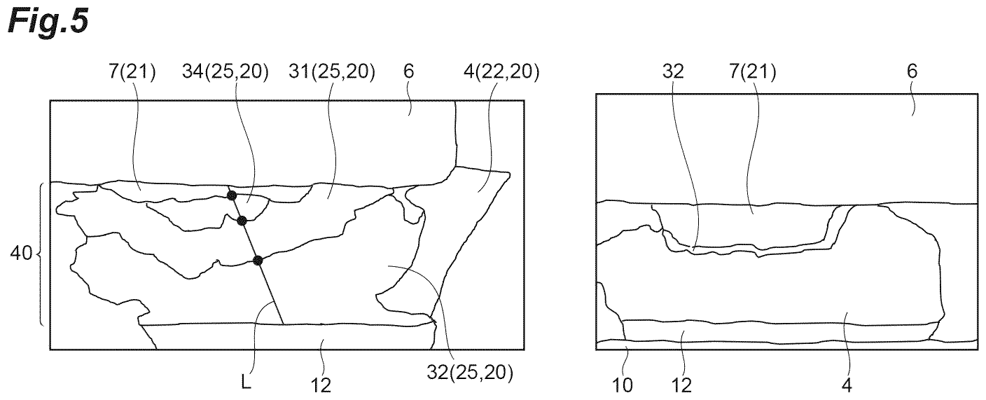

Methods for measuring the thickness and area of each layer in the above-described bonded structure 100 will be described with reference to FIG. 5(a). First, the vicinity of the center of the obtained bonded structure 100 is cut out perpendicularly to the wiring substrate 3, and the phase identification of each layer is performed from the element ratio by SEM-EDS measurement. A midpoint of a cross-section where the terminal 7 on the electronic component 2 side in the cross-section is in contact with the body portion 6 of the electronic component 2 and a midpoint of a cross-section where the bonding layer 40 on the wiring substrate 3 side is in contact with the terminal 10 (conductive film 12) are connected by a straight line L, and the length of the straight line L passing through each layer is taken as the layer thickness. The ratio of the thickness of the bonding material 4 can be calculated from the obtained result of the thickness of each layer.

Furthermore, the area of each layer of the bonded structure 100 can be calculated by measuring the area of each layer in an SEM image. From the obtained result of the area of each layer, the volume of each layer is obtained, whereby the ratio of the volumes of the bonding material 4 and the terminal 7 described above can be calculated.

As the method for measuring the thickness of each layer of the bonded structure 100, a method of approximating the boundary of each layer to a line segment by a least square approximation method and measuring a distance between midpoints as the layer thickness may be adopted. Based on the measurement method, the thickness of the bonding material 4 (second metal layer 22) may be 50% or less of the total thickness of the terminal 7 (first metal layer 21), the intermetallic compound layer 25, and the bonding material 4.

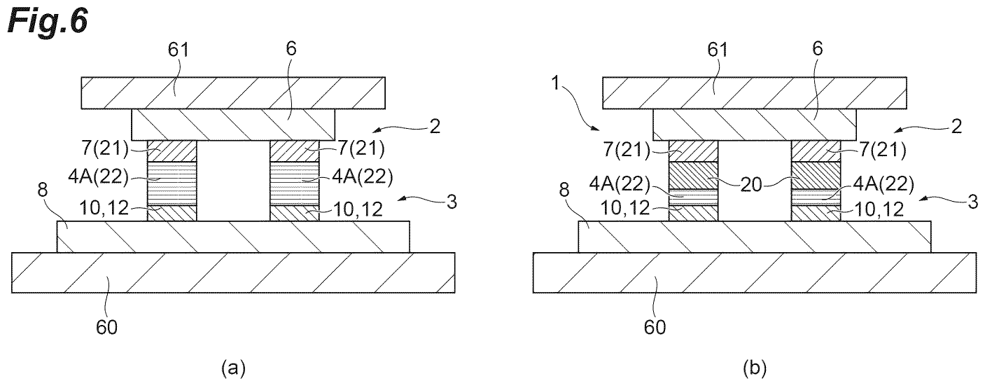

Next, referring to FIG. 6, a method for bonding the electronic component 2 and the wiring substrate 3 will be described. First, as illustrated in FIG. 6(a), the terminal 7 of the electronic component 2 is placed on the bonding material 4A of the wiring substrate 3. Here, when heating is performed at a temperature exceeding the melting point of Sn for a long time (several minutes), the entire structure becomes a eutectic structure, and making it difficult for the intermetallic compound layer 25 of the bonded structure 100 to form distinct layers. Therefore, a desired stacked structure may be formed by controlling a treatment temperature, a treatment time, and a pressurizing force by solid phase diffusion that does not generate a liquid phase, or may be formed by controlling a temperature gradient during a bonding treatment by liquid phase bonding. For example, a heating plate 61 is brought into contact with the electronic component 2 side, and a cooling plate 60 is brought into contact with the wiring substrate 3 side to dissolve only the contact portion between the first metal layer 21 containing a first metal and the second metal layer 22 containing a second metal. In addition, not the eutectic structure but the stacked structure can be obtained by gradually moving the melting point to the wiring substrate 3 side by lowering a heating temperature and increasing a cooling temperature (FIG. 4(b)).

Next, functions and effects of the bonded structure 100 according to the present embodiment will be described.

The bonded structure 100 according to the present embodiment is the bonded structure 100 in which the electronic component 2 and the wiring substrate 3 are bonded to each other, the bonded structure including, in order from the electronic component 2 side: the first metal layer 21 containing a metal forming an intermetallic compound with Sn; the intermetallic compound layer 25 composed of an intermetallic compound containing Sn; and the second metal layer 22 containing Sn. The thickness of the second metal layer 22 is 50% or less of the total thickness of the first metal layer 21, the intermetallic compound layer 25, and the second metal layer 22.

In the bonded structure 100 according to the present embodiment, the thickness of the second metal layer 22 is 50% or less of the total thickness of the first metal layer 21, the intermetallic compound layer 25, and the second metal layer 22. This means that a metal element (Au) forming an intermetallic compound with Sn in the initial state of bonding exists in a range wider than a central portion of the bonded structure 100. In this case, a concentration gradient serving as a driving force of diffusion of a metal element forming an intermetallic compound with Sn can be reduced, and Kirkendall void formation can be suppressed.

The first metal layer 21 may contain Au. Au is a metal element in which a Kirkendall void is likely to be formed because Au is likely to form an intermetallic compound with Sn and Au is likely to diffuse in a layer containing Sn. On the other hand, by adopting the structure of the present embodiment, it is possible to suppress Kirkendall void formation even in the case of using Au.

The intermetallic compound layer 25 may be present on the terminal 10 (conductive film 12) of the wiring substrate 3. When the intermetallic compound layer 25 containing Sn is present on the terminal 10 of the wiring substrate 3, the concentration gradient of the metal element forming an intermetallic compound with Sn is low, diffusion hardly occurs, and Kirkendall void formation can be suppressed.

The terminal 10 of the wiring substrate 3 may have the conductive film 12 containing Ni formed on a surface thereof. The conductive film 12 containing Ni can suppress a reaction between the inside of the terminal 10 of the wiring substrate 3 and the metal element forming an intermetallic compound with Sn. This makes it possible to suppress the diffusion length extension of the metal element forming an intermetallic compound with Sn and to suppress Kirkendall void formation.

The volume ratio of the second metal layer 22 may be 50% or less of the total volume of the first metal layer 21, the intermetallic compound layer 25, and the second metal layer 22. This makes it difficult for the metal element forming an intermetallic compound with Sn to diffuse, and Kirkendall void formation can be suppressed.

The volume ratio of the first metal layer 21 may be 50% or less of the total volume of the first metal layer 21, the intermetallic compound layer 25, and the second metal layer 22. By reducing the volume of the first metal layer 21 containing a metal element forming an intermetallic compound with Sn, the element to be diffused can be reduced, and Kirkendall void formation can be suppressed.

The bonded structure 100 according to the present embodiment is the bonded structure 100 in which the electronic component 2 and the wiring substrate 3 are bonded to each other, the bonded structure including, in order from the electronic component 2 side: the first metal layer 21 containing a metal forming an intermetallic compound with Sn; and the intermetallic compound layer 25 composed of an intermetallic compound containing Sn, in which the intermetallic compound layer 25 is present on the terminal 10 of the wiring substrate 3.

The bonded structure 100 according to the present embodiment is not a eutectic structure but a stacked structure of the first metal layer 21 containing a metal forming an intermetallic compound with Sn and an intermetallic compound containing Sn. Furthermore, the intermetallic compound layer 25 reaches the terminal 10 of the wiring substrate 3. Therefore, the concentration gradient of the metal element forming an intermetallic compound with Sn, which serves a driving force of diffusion, can be reduced, and Kirkendall void formation can be suppressed.

The terminal 10 of the wiring substrate 3 may have the conductive film 12 containing Ni formed on a surface thereof. The conductive film 12 containing Ni can suppress a reaction between the inside of the terminal 10 of the wiring substrate 3 and the metal element forming an intermetallic compound with Sn. This makes it possible to suppress the diffusion length extension of the metal element forming an intermetallic compound with Sn and to suppress Kirkendall void formation.

The bonded structure 100 according to the present embodiment is the bonded structure 100 in which the electronic component 2 and the wiring substrate 3 are bonded to each other, the bonded structure including: the first metal layer 21 containing a metal forming an intermetallic compound with Sn; the intermetallic compound layer 25 composed of an intermetallic compound containing Sn; and the second metal layer 22 containing Sn, in which a volume ratio of the second metal layer 22 may be 50% or less of a total volume of the first metal layer 21, the intermetallic compound layer 25, and the second metal layer 22.

In the bonded structure 100 according to the present embodiment, the volume ratio of the second metal layer 22 is 50% or less of the total volume of the first metal layer 21, the intermetallic compound layer 25, and the second metal layer 22. This means that a metal element forming an intermetallic compound with Sn in the initial state of bonding exists in a wide range in the bonded structure. In this case, a concentration gradient serving as a driving force of diffusion of a metal element forming an intermetallic compound with Sn can be reduced, and Kirkendall void formation can be suppressed.

The present disclosure is not limited to the above-described embodiment.

The arrangement, size, and number of layers in the bonded structure are not particularly limited, and may be appropriately changed within the scope of the present disclosure.

### EXAMPLES

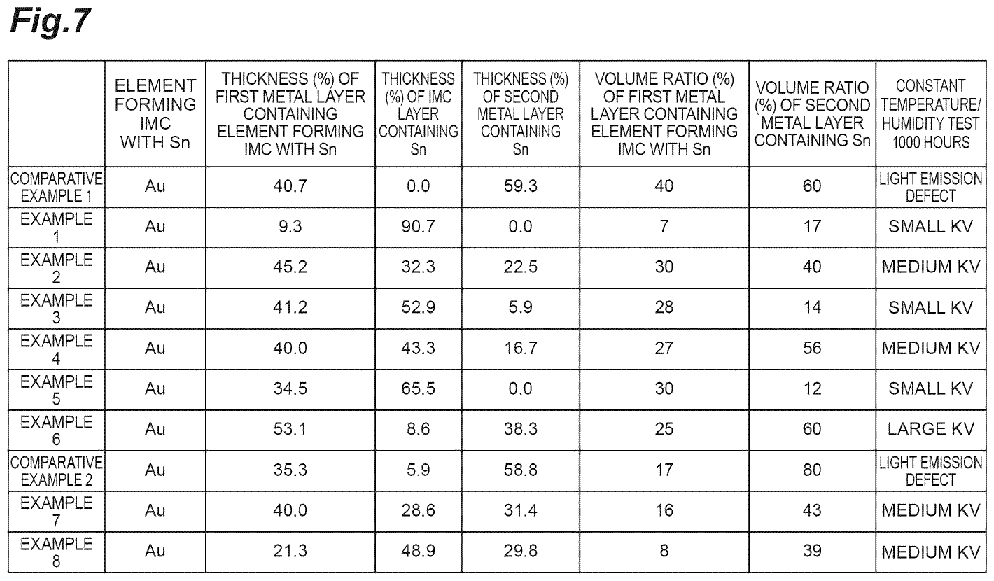

Referring to FIG. 7, Examples 1 to 8 and Comparative Examples 1 and 2 will be described. However, the present disclosure is not limited to these Examples. First, the method for manufacturing the mounting board 1 according to Examples and Comparative Examples will be described. An LED was prepared as the electronic component 2, and the terminal 7 of Au was formed on the LED. After an electrodeposition layer of the conductive film 12 of Ni was formed on the terminal 10 of Cu on the substrate side, the bonding material 4A of Sn was formed on the conductive film 12. In a state where the terminal 7 of Au of the electronic component 2 and the bonding material 4A of Sn of the wiring substrate 3 were in contact with each other, the cooling plate 60 was brought into contact with the wiring substrate 3 side so that the temperature of the wiring substrate 3 side was always 50° C. while applying a pressure of 0.05 to 0.20 MPa, the heating plate 61 of 300° C. to 310° C. was brought into contact with the electronic component 2 side, the temperature of the cooling plate 60 was appropriately raised and the temperature of the heating plate 61 was lowered when the contact surface started to react, and the thickness of the intermetallic compound layer 25 was controlled to obtain a bonded structure.

Examples 1 to 6 and Comparative Examples 1 and 2 were manufactured under the same conditions except that the temperature control was adjusted. Examples 7 and 8 were formed under the same conditions except that the area of electrodeposition of the bonding material 4A of Sn was made five times as large as that in Example 2, and the current during electrodeposition was adjusted so that the height of the bonding material 4A was the same. The thickness of each layer of the bonding layer 40 was measured by the above-described method of performing phase identification of each layer from the element ratio by SEM-EDS measurement and measuring the thickness of each layer of the bonding layer 40 from the SEM image. The ratio of the thickness of each layer to the entire bonding layer 40 is shown in FIG. 7. Furthermore, the area of each layer was measured from the SEM image, and based on the area, the ratio of the volumes of the first metal layer 21 and the second metal layer 22 to the volume of the entire bonding layer 40 was measured by the above-described method. The ratio is shown in FIG. 7. Next, the mounting board 1 of each of Examples 1 to 8 and Comparative Examples 1 and 2 was put into a constant temperature/humidity test, a light emission experiment of the mounting board 1 after the test was performed, the vicinity of the center of the bonding layer 40 was then cut out perpendicularly to the wiring substrate 3, and the number of KVs (Kirkendall voids) in the cross-section was measured. Measurement results are shown in FIG. 7. Note that, the SEM image of Example 1 is shown in FIG. 5(a), and the SEM image of Comparative Example 2 is shown in FIG. 5(b). In Example 1, an AuSn layer 34 is formed on the lower side of the terminal 7.

In Comparative Example 1, it is considered that the amount of the intermetallic compound layer was 0%, Au and Sn were not bonded, and Au and Sn were in contact with each other to emit light before the test, but the contact portion was separated after the test and light was not emitted. In Comparative Example 2, it is considered that diffusion of Au was insufficient, a large amount of KV was generated, the bonding layer 40 was broken, and no light was emitted. In Example 6, it is considered that a small amount of Au was diffused into Sn before the test, so that the light emission defect was suppressed without causing breakage. In Examples 2 and 4, it is considered that Au was diffused in Sn before the test, and the number of occurrences of KV after the test was smaller than that in Example 6. In Examples 1, 3, and 5, it is considered that a large amount of Au was diffused in Sn before the test, and the number of occurrences of KV after the test was smaller than that in Examples 2, 4, and 6. From Examples 7 and 8, it is considered that the effect of the present disclosure can be obtained as long as the thickness ratio is the same even when the precipitation volume of the Sn alloy increases.

### Embodiment 1

A bonded structure in which an electronic component and a wiring substrate are bonded to each other, the bonded structure including, in order from the electronic component side:
a first metal layer containing a metal forming an intermetallic compound with Sn;
an intermetallic compound layer composed of an intermetallic compound containing Sn; and
a second metal layer containing Sn, wherein a thickness of the second metal layer is 50% or less of a total thickness of the first metal layer, the intermetallic compound layer, and the second metal layer.

### Embodiment 2

The bonded structure according to embodiment 1, wherein the first metal layer contains Au.

### Embodiment 3

The bonded structure according to embodiment 1 or 2, wherein the intermetallic compound layer is present on a terminal of the wiring substrate.

### Embodiment 4

The bonded structure according to any one of embodiments 1 to 3, wherein the terminal of the wiring substrate has a conductive film containing Ni formed on a surface thereof.

### Embodiment 5

The bonded structure according to any one of embodiments 1 to 4, wherein a volume ratio of the second metal layer is 50% or less of a total volume of the first metal layer, the intermetallic compound layer, and the second metal layer.

### Embodiment 6

The bonded structure according to any one of embodiments 1 to 5, wherein a volume ratio of the first metal layer is 50% or less of the total volume of the first metal layer, the intermetallic compound layer, and the second metal layer.

### Embodiment 7

A bonded structure in which an electronic component and a wiring substrate are bonded to each other, the bonded structure including, in order from the electronic component side:
a first metal layer containing a metal forming an intermetallic compound with Sn; and
an intermetallic compound layer composed of an intermetallic compound containing Sn, wherein
the intermetallic compound layer is present on a terminal of the wiring substrate.

### Embodiment 8

The bonded structure according to embodiment 7, wherein the terminal of the wiring substrate has a conductive film containing Ni formed on a surface thereof.

### Embodiment 9

A bonded structure in which an electronic component and a wiring substrate are bonded to each other, the bonded structure including: a first metal layer containing a metal forming an intermetallic compound with Sn;
an intermetallic compound layer composed of an intermetallic compound containing Sn; and
a second metal layer containing Sn, wherein a volume ratio of the second metal layer is 50% or less of a total volume of the first metal layer, the intermetallic compound layer, and the second metal layer.

### REFERENCE SIGNS LIST

2 . . . Electronic component, 3 . . . Wiring substrate, 10 . . . Terminal, 12 . . . Conductive film, 21 . . . . First metal layer, 22 . . . . Second metal layer, 25 . . . Intermetallic compound layer, 100 . . . Bonded structure.

1. A bonded structure in which an electronic component and a wiring substrate are bonded to each other, the bonded structure comprising, in order from the electronic component side:
a first metal layer containing a metal forming an intermetallic compound with Sn;
an intermetallic compound layer composed of an intermetallic compound containing Sn; and
a second metal layer containing Sn, wherein
a thickness of the second metal layer is 50% or less of a total thickness of the first metal layer, the intermetallic compound layer, and the second metal layer.

2. The bonded structure according to claim 1, wherein the first metal layer contains Au.

3. The bonded structure according to claim 1, wherein the intermetallic compound layer is present on a terminal of the wiring substrate.

4. The bonded structure according to claim 1, wherein the terminal of the wiring substrate has a conductive film containing Ni formed on a surface thereof.

5. The bonded structure according to claim 1, wherein a volume ratio of the second metal layer is 50% or less of a total volume of the first metal layer, the intermetallic compound layer, and the second metal layer.

6. The bonded structure according to claim 1, wherein a volume ratio of the first metal layer is 50% or less of a total volume of the first metal layer, the intermetallic compound layer, and the second metal layer.

7. A bonded structure in which an electronic component and a wiring substrate are bonded to each other, the bonded structure comprising, in order from the electronic component side:
a first metal layer containing a metal forming an intermetallic compound with Sn; and
an intermetallic compound layer composed of an intermetallic compound containing Sn, wherein
the intermetallic compound layer is present on a terminal of the wiring substrate.

8. The bonded structure according to claim 7, wherein the terminal of the wiring substrate has a conductive film containing Ni formed on a surface thereof.

9. A bonded structure in which an electronic component and a wiring substrate are bonded to each other, the bonded structure comprising:
a first metal layer containing a metal forming an intermetallic compound with Sn;
an intermetallic compound layer composed of an intermetallic compound containing Sn; and
a second metal layer containing Sn, wherein
a volume ratio of the second metal layer is 50% or less of a total volume of the first metal layer, the intermetallic compound layer, and the second metal layer.

10. The bonded structure according to claim 1, wherein the bonded structure does not have a eutectic structure.

11. The bonded structure according to claim 7, wherein the bonded structure does not have a eutectic structure.

12. The bonded structure according to claim 9, wherein the bonded structure does not have a eutectic structure.

13. The bonded structure according to claim 7, wherein the first metal layer contains Au.

14. The bonded structure according to claim 9, wherein the first metal layer contains Au.

15. The bonded structure according to claim 7, wherein the intermetallic compound layer is in direct contact with the terminal.

16. The bonded structure according to claim 8, wherein the intermetallic compound layer is in direct contact with the conductive film provided on the terminal.

17. The bonded structure according to claim 7, further comprising a second metal layer containing Sn, wherein a volume ratio of the second metal layer is 50% or less of a total volume of the first metal layer, the intermetallic compound layer, and the second metal layer.

18. The bonded structure according to claim 7, further comprising a second metal layer containing Sn, wherein a volume ratio of the first metal layer is 50% or less of a total volume of the first metal layer, the intermetallic compound layer, and the second metal layer.

19. The bonded structure according to claim 9, wherein a volume ratio of the first metal layer is 50% or less of a total volume of the first metal layer, the intermetallic compound layer, and the second metal layer.
